(19) United States
(12) Patent Application Publication
(10) Pub. No.: US 2015/0170928 A1
(43) Pub. Date: Jun. 18, 2015

(54) SILICON CARBIDE SUBSTRATE AND FABRICATION METHOD THEREOF

(71) Applicant: SUMITOMO ELECTRIC INDUSTRIES, LTD., Osaka (JP)

(72) Inventor: Masahiro NAKAYAMA, Itami-shi (JP)

(73) Assignee: SUMITOMO ELECTRIC INDUSTRIES, LTD., Osaka (JP)

(21) Appl. No.: 14/107,303

(22) Filed: Dec. 16, 2013

(51) Int. Cl. H01L 21/306; C01B 31/36

(52) U.S. Cl. CPC H01L 21/30625; C01B 31/36

(57) ABSTRACT

A fabrication method of a silicon carbide substrate includes the following steps. By slicing a silicon carbide ingot, a first intermediate substrate having a first main surface and second main surface opposite to each other and a first SORI value, is formed. By etching at least one of the first main surface and the second main surface of the first intermediate substrate, a second intermediate substrate having a second SORI value smaller than the first SORI value is formed. By grinding at least one of the first main surface and the second main surface of the second intermediate substrate, a third intermediate substrate having a third SORI value greater than the second SORI value is formed. Accordingly, a silicon carbide substrate with small warpage is provided.

### BACKGROUND OF THE INVENTION

1. Field of the Invention

The present invention relates to a silicon carbide substrate, and a fabrication method thereof, particularly a silicon carbide substrate that can have warpage at the silicon carbide substrate reduced, and a method of fabricating the silicon carbide substrate.

2. Description of the Background Art

In recent years, silicon carbide substrates are now being used for fabricating semiconductor devices. Silicon carbide has a bandgap wider than that of silicon. Since a semiconductor device employing a silicon carbide substrate has high breakdown electric field and also high saturation electron mobility, superior characteristics such as small property degradation under high temperature environment, high breakdown voltage, and low ON resistance can be exhibited.

Japanese Patent Laying-Open No. 2008-227534, for example, discloses a method of fabricating a silicon carbide substrate. The publication teaches a method including the steps of cutting out a silicon carbide substrate by severing a body of silicon carbide using a wire saw, and then removing the damaged layer using a lapping device. According to the fabrication method of a silicon carbide substrate disclosed in this publication, a silicon carbide substrate having warpage less than or equal to ±50 μm and a surface roughness Ra less than or equal to 1 nm can be fabricated.

However, when a silicon carbide substrate is cut out from a body of silicon carbide using a wire saw, there was a case where great warpage is generated depending upon the cutting direction. In the case where such a silicon carbide substrate having great warpage is to be ground, attachment to a grinding plate at high accuracy was difficult, and/or the silicon carbide substrate would fall off from the grinding carrier. It was not easy to achieve favorable grinding. Thus, fabrication of a silicon carbide substrate with small warpage was difficult.

### SUMMARY OF THE INVENTION

In view of the foregoing, an object of the present invention is to provide a silicon carbide substrate with small warpage.

A fabrication method of a silicon carbide substrate according to the present invention includes the following steps. A first intermediate substrate having a first main surface and a second main surface opposite to each other, and a first SORI value, is formed by slicing a silicon carbide ingot. By etching at least one of the first main surface and second main surface of the first intermediate substrate, a second intermediate substrate having a second SORI value lower than the first SORI value is formed. By grinding at least one of the first main surface and second main surface of the second intermediate substrate, a third intermediate substrate having a third SORI value lower than the second SORI value is formed.

By etching at least one of the first main surface and second main surface of the first intermediate substrate according to a fabrication method of a silicon carbide substrate of the present invention, a second intermediate substrate having a second SORI value lower than the first SORI value is formed. Then, at least one of the first main surface and second main surface of the second intermediate substrate is ground. In other words, the step of grinding the silicon carbide substrate is performed after the warpage at the silicon carbide substrate is reduced by etching. These measures can suppress the aforementioned inconvenient event of the silicon carbide substrate not being able to be attached to the grinding plate accurately or the drop off from the grinding carrier during grinding due to the conventional silicon carbide substrate having great warpage can be suppressed. As a result, the silicon carbide substrate is ground favorably, leading to reducing warpage at the silicon carbide substrate.

Preferably in the fabrication method of a silicon carbide substrate set forth above, both the first main surface and second main surface of the third intermediate substrate are subject to CMP. Accordingly, the warpage at the silicon carbide substrate can be further reduced.

Preferably in the fabrication method of a silicon carbide substrate set forth above, the step of forming a third intermediate substrate is performed by grinding both the first main surface and second main surface of the second intermediate substrate simultaneously. Accordingly, the time required for fabricating a silicon carbide substrate can be shortened while reducing warpage at the silicon carbide substrate.

Preferably, in the step of fabricating a silicon carbide substrate set forth above, the step of forming a second intermediate substrate includes the step of wet-etching at least one of the first main surface and the second main surface of the first intermediate substrate using potassium hydroxide. Accordingly, a second intermediate layer of small warpage can be fabricated efficiently.

Preferably in the fabrication method of a silicon carbide substrate set forth above, the step of forming a second intermediate substrate includes the step of dry-etching at least one of the first main surface and the second main surface of the first intermediate substrate using chlorine gas or fluorine gas. Accordingly, a second intermediate substrate with small warpage can be fabricated efficiently.

Preferably in a fabrication method of a silicon carbide substrate set forth above, the step of forming a second intermediate substrate is performed by etching both the first main surface and the second main surface of the first intermediate substrate. Accordingly, a second intermediate substrate with small warpage can be fabricated more efficiently.

Preferably in the fabrication method of a silicon carbide substrate set forth above, at the step of forming a second intermediate substrate, the first intermediate substrate is etched such that the SORI value in a direction perpendicular to the direction of slicing the ingot is reduced. Warpage at the first intermediate substrate readily occurs in a direction perpendicular to the direction of slicing the ingot. By performing etching such that the SORI value in the direction perpendicular to the direction of slicing the ingot is reduced, a second intermediate substrate with small warpage can be fabricated more efficiently.

The silicon carbide substrate of the present invention includes a first main surface and a second main surface opposite to each other. The first main surface has a surface roughness Rms less than or equal to 0.2 nm. The second main surface has a surface roughness Rms less than 10 nm. The SORI value is less than or equal to 23 μm and a TTV value is less than or equal to 3 μm. The diameter is greater than or equal to 4 inches.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a perspective view schematically representing a configuration of a silicon carbide substrate according to a first embodiment of the present invention.

FIG. 2 is a sectional view schematically representing a configuration of a silicon carbide substrate according to the first embodiment of the present invention.

FIG. 3 is a schematic plan view to describe the definition of SORI and TTV.

FIGS. 4 and 5 are schematic sectional views to describe the definition of SORI and TTV.

FIG. 6 is a flowchart schematically representing a fabrication method of a silicon carbide substrate according to the first embodiment of the present invention.

FIGS. 7 and 8 are a plan view and a front view, respectively, schematically representing a slicing step in a fabrication method of a silicon carbide substrate according to the first embodiment of the present invention.

FIG. 9 is a schematic plan view to describe the direction of SORI at the silicon carbide substrate according to the first embodiment of the present invention.

FIG. 10 is a sectional view schematically representing a grinding step in the fabrication method of a silicon carbide substrate according to the first embodiment of the present invention.

FIGS. 11, 12, 13 and 14 are sectional views schematically representing a first intermediate substrate, a second intermediate substrate, a third intermediate substrate, and a fourth intermediate substrate, respectively, according to the first embodiment of the present invention.

FIG. 15 is a flowchart schematically representing a fabrication method of a silicon carbide substrate according to a second embodiment of the present invention.

FIG. 16 is a sectional view schematically representing a grinding step in the fabrication method of a silicon carbide substrate according to the second embodiment of the present invention.

FIG. 17 is a schematic plan view to describe the positioning relationship between a carrier and the second intermediate substrate at a grinding step in the fabrication method of a silicon carbide substrate according to the second embodiment of the present invention.

### DESCRIPTION OF THE PREFERRED EMBODIMENTS

Embodiments of the present invention will be described hereinafter with reference to the drawings. In the drawings, the same or corresponding elements have the same reference characters allotted, and description thereof will not be repeated.

As to the crystallographic notation in the present specification, a specific orientation is represented by [ ], a group of orientations is represented by < >, a specific plane is represented by ( ) and a group of equivalent planes is represented by { }. For a negative index, a bar (-) is typically allotted above a numerical value in the crystallographic aspect. However, in the present specification, a negative sign will be attached before the numerical value. Further, the angle is defined using a system based on an omnidirectional range of 360 degrees.

### First Embodiment

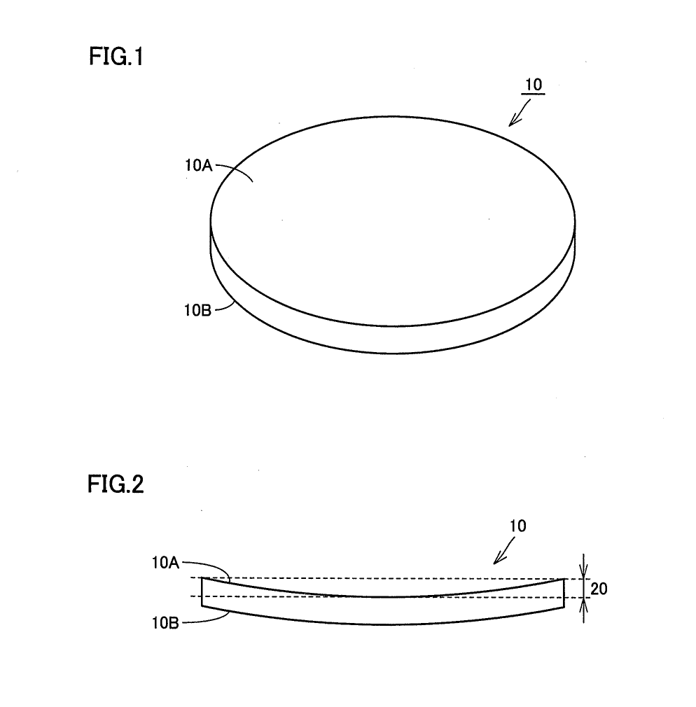

A configuration of a silicon carbide substrate according to a first embodiment of the present invention will be described hereinafter with reference to FIGS. 1 and 2.

As shown in FIGS. 1 and 2, a silicon carbide substrate 10 according to the first embodiment of the present invention includes a first main surface 10A and a second main surface 10B opposite to each other. Silicon carbide substrate 10 is formed of silicon carbide single crystal, for example. The silicon carbide single crystal has a hexagonal crystal structure of the 4H polytype, for example. At least one of first main surface 10A and second main surface 10B is, for example, the {03-38} plane. At least one of first main surface 10A and second main surface 10B may be a {0-11-1} plane or {0-11-2} plane, or may be a plane having an off angle of 62°±10° microscopically relative to a {000-1} plane.

First main surface 10A is mirror-polished, having a surface roughness Rms (root mean square) less than or equal to 0.2 nm. Second main surface 10B is the back side surface, having a surface roughness Rms less than 10 nm. Surface roughness Rms can be measured by an AFM (Atomic Force Microscope), for example.

According to the present embodiment, first main surface 10A has a surface roughness Rms of approximately 0.073 nm, for example, and a surface roughness Ra (mean surface roughness) of approximately 0.057 nm, for example. Second main surface 10B has a surface roughness Rms of approximately 4-6 nm, for example. Silicon carbide substrate 10 of the present embodiment is at least 4 inches, for example, in diameter. The SORI (warpage) value is less than or equal to 23 μm and the TTV (Total Thickness Variation) value is less than or equal to 3 μm.

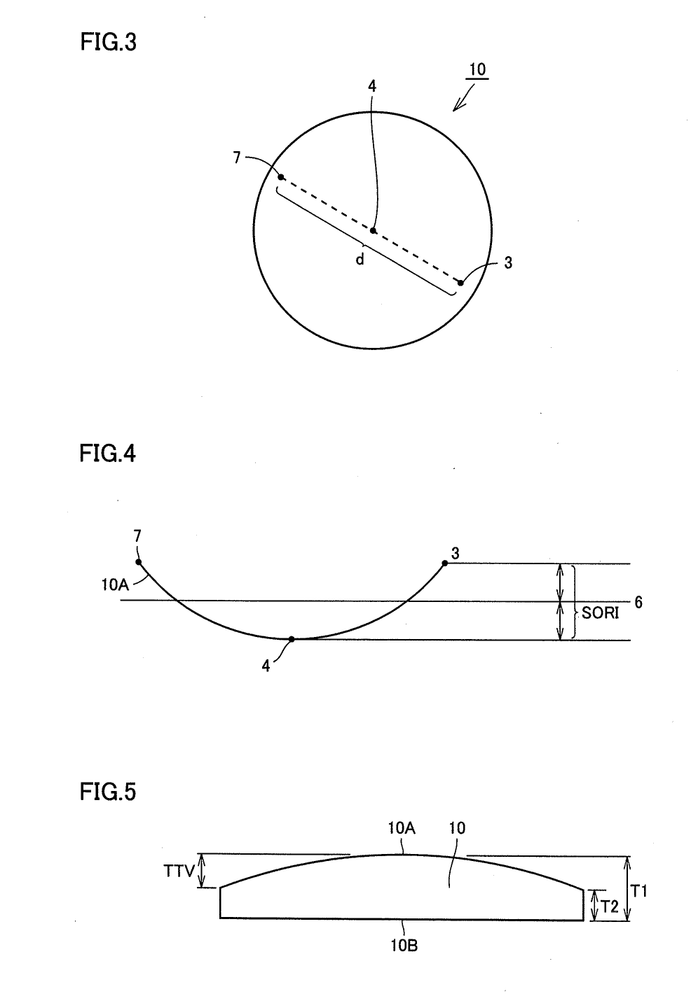

The definition of a SORI value and TTV value will be described hereinafter with reference to FIGS. 3-5.

First, a SORI value will be described with reference to FIGS. 3 and 4. A SORI value is a parameter to quantize the degree of warpage of the silicon carbide substrate. A SORI value represents a total value of the distance between the height of a position 3 (highest point) of first main surface 10A and the reference height and the distance between the height of a position 4 (lowest point) and the reference height, where the least square plane of first main surface 10A of silicon carbide substrate 10 is taken as the reference height (least squares plane height 6). The SORI value always takes a positive value since it represents the distance. The SORI value is calculated relative to a silicon carbide substrate 10 not clamped.

Moreover, the SORI value represents the degree of warpage in a certain measured range. For example, the SORI value is determined between a certain position 7 to another position 3 (range d) of silicon carbide substrate 10. In the present embodiment, the SORI value of silicon carbide substrate 10 refers to the maximum value from the SORI values between two arbitrary points on a main surface of silicon carbide substrate 10 (first main surface 10A or second main surface 10B).

Generally, the SORI value of first main surface 10A and the SORI value of second main surface 10B opposite to each other take substantially the same value. Therefore, the SORI value of silicon carbide substrate 10 is determined in a one-to-one correspondence. When the SORI value of first main surface 10A differs from the SORI value of second main surface 10B, the SORI value of silicon carbide substrate 10 refers to the larger of the SORI value of first main surface 10A and the SORI value of second main surface 10B.

A TTV value is a parameter to quantize variation in the thickness of silicon carbide substrate 10. For example, it is assumed that one of first main surface 10A and second main surface 10B opposite to each other of silicon carbide substrate 10 is a flat plane (for example, second main surface 10B). An imaginary silicon carbide substrate 10 having the height of first main surface 10A opposite to second main surface 10B determined such that the thickness at each location of silicon carbide substrate 10 is equal is shown in FIG. 5. A TTV value is calculated as the difference between the maximum thickness and minimum thickness (namely, T1-T2), where T1 is the maximum thickness and T2 is the minimum thickness of imaginary silicon carbide substrate 10 shown in FIG. 5. The TTV value is calculated for silicon carbide substrate 10 having the back side clamped.

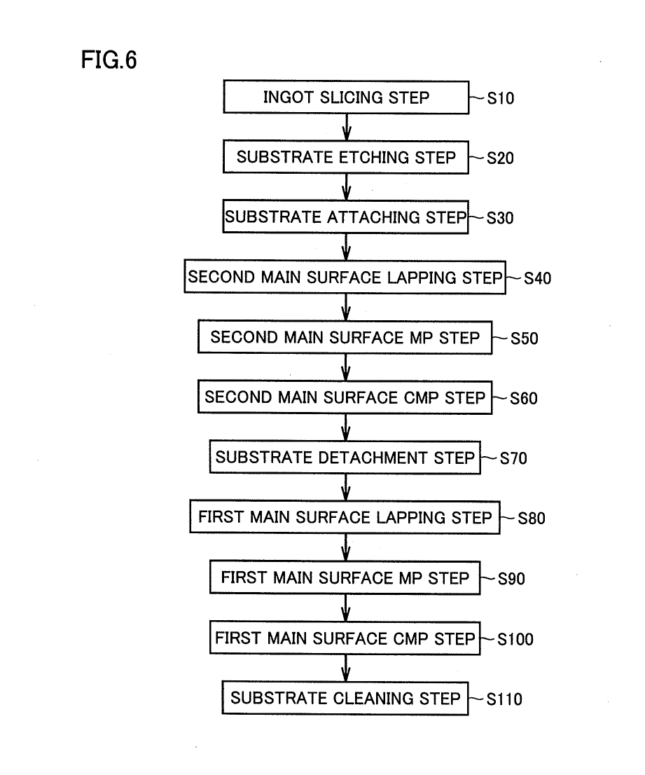

A fabrication method of silicon carbide substrate 10 according to the first embodiment of the present invention will be described hereinafter with reference to FIG. 6.

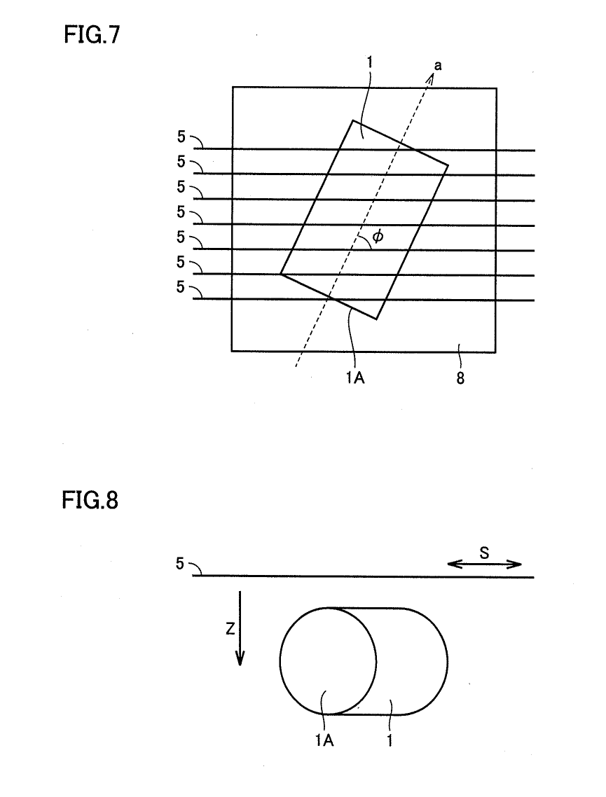

First, an ingot slicing step (S10: FIG. 6) is performed. Specifically, an ingot 1 formed of silicon carbide is fixed to a base (not shown) formed of carbon, for example. As shown in FIG. 7, ingot 1 in a state fixed to a base is arranged on a slicer stage 8. A plurality of saw wires 5 are arranged above stage 8. Ingot 1 is arranged such that the main surface of the intermediate substrate cut by saw wire 5 corresponds to the desired plane. For example, ingot 1 is arranged on slicer stage 8 such that an angle Φ between a growing direction a of ingot 1 (that is, the <0001> direction) and the extending direction of saw wire 5 becomes 54.7°, for example.

Referring to FIG. 8, saw wire 5 is moved back and forth along an extending direction S of saw wire 5 while ingot 1 and saw wire 5 are made to come closer relative to each other. In this case, saw wire 5 may be moved to approach ingot 1, or ingot 1 may be moved to approach saw wire 5. By the contact between ingot 1 and saw wire 5 and the reciprocating movement of saw wire 5 along extending direction S, the cutting of ingot 1 is initiated. For example, by moving ingot 1 in a direction perpendicular to extending direction S of saw wire 5, ingot 1 is cut. The direction Z of slicing ingot 1 in the present specification refers to the moving direction of ingot 1 or saw wire 5 from the start to the end of the cutting operation of ingot 1. The cutting of ingot 1 may be performed using loose grains, or using fixed abrasive grains bonded to a wire, for example. Diamond grains, for example, are employed for cutting ingot 1.

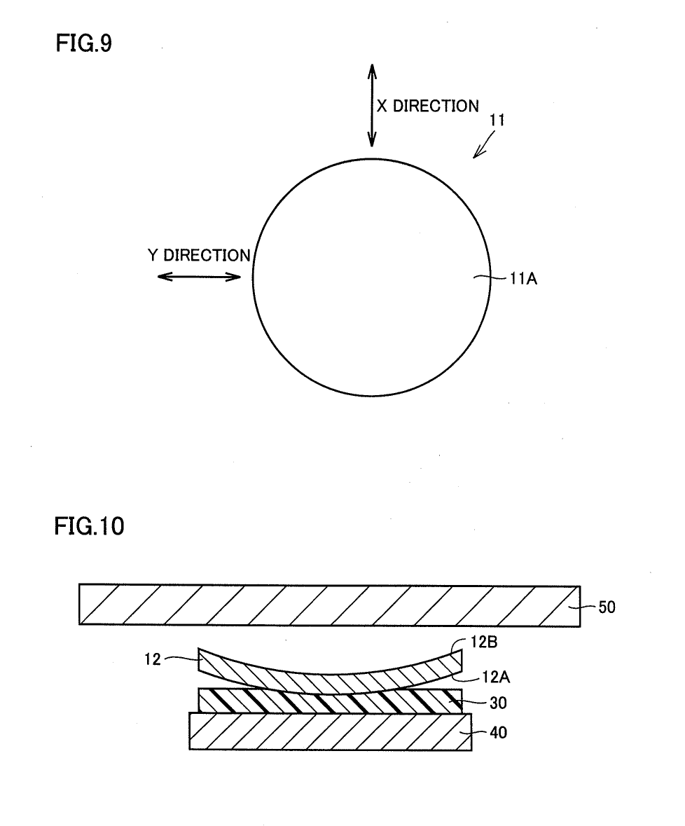

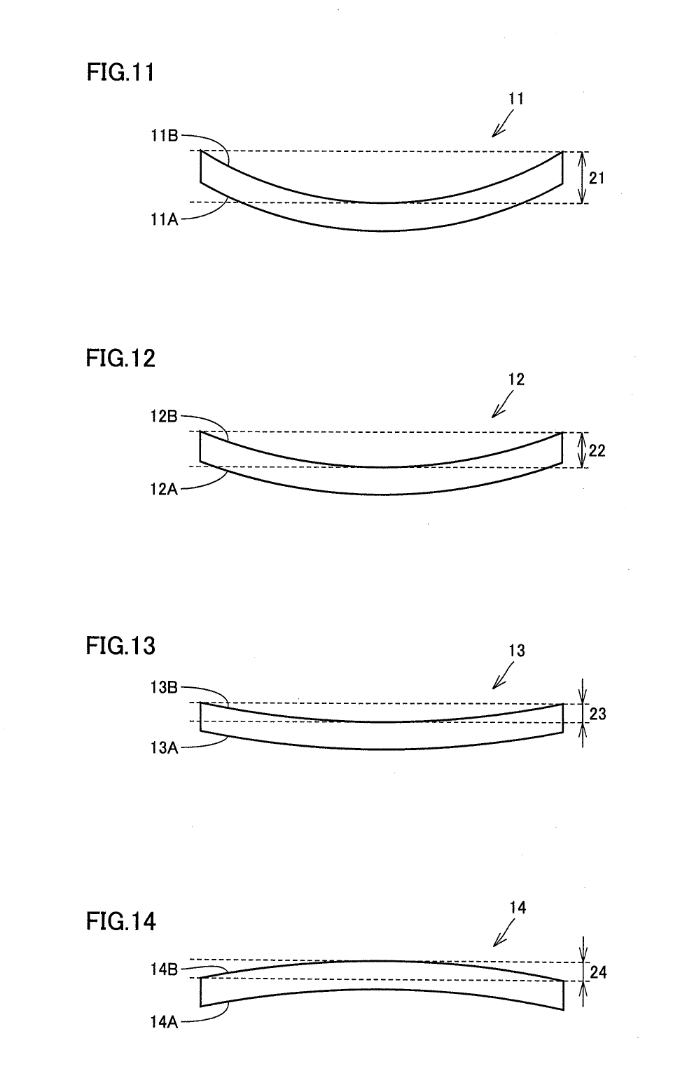

By slicing ingot 1 formed of silicon carbide as set forth above, a first intermediate substrate 11 (refer to FIG. 11) having a first main surface 11A and a second main surface 11B opposite to each other, and a first SORI value 21, is formed. FIG. 9 corresponds to the case where first intermediate substrate 11 having a first main surface 11A of the (03-38) plane, for example, is formed. First SORI value 21 along the direction (X direction) of slicing ingot 1 (that is, the <11-20> direction) is approximately 13 μm (measurement range 40 mm), whereas first SORI value 21 along a direction <01-10> (Y direction) perpendicular to the slicing direction is approximately 10 μm (measurement range 20 mm). The radius of curvature is 5 m. In other words, the SORI value is approximately 250 μM immediately after the slicing step based on the calculation of a 4-inch substrate.

Then, a substrate etching step (S20: FIG. 6) is performed. In this step, at least one of first main surface 11A and second main surface 11B of first intermediate substrate 11 cut out by the aforementioned step (S10: FIG. 6) is etched. Preferably, both first main surface 11A and second main surface 11B of first intermediate substrate 11 are etched. The etching process may be wet etching or dry etching. As a specific example of wet etching, an etching step is performed by immersing first intermediate substrate 11 in molten KOH (potassium hydroxide) at approximately 520° C. The period of time immersed in molten KOH is greater than or equal to 5 minutes and less than or equal to 8 minutes, for example. The amount removed from first intermediate substrate 11 by the relevant etching is approximately greater than or equal to 3 μm and less than or equal to 10 μm. As a specific example of dry etching, an etching step is performed under an atmosphere in which chlorine gas and oxygen gas are introduced to at least one of first main surface 11A and second main surface 11B of first intermediate substrate 11, for example. Preferably, dry etching is performed using chlorine gas or fluorine gas. The amount removed from first intermediate substrate 11 by the relevant etching is, for example, greater than or equal to 1 μm and less than or equal to 3 μm.

Thus, the damaged layer formed at first main surface 11A and second main surface 11B of first intermediate substrate 11 at the aforementioned step (S10: FIG. 6) is removed partially or completely. Accordingly, the warpage at first intermediate substrate 11 is reduced. In other words, by etching at least one of first main surface 11A and second main surface 11B of first intermediate substrate 11, a second intermediate substrate 12 (refer to FIG. 12) having a second SORI value 22 smaller than first SORI value 21 is formed. Second SORI value 22 along a direction perpendicular to the slicing direction (that is the <01-10> direction) at second intermediate substrate 12 is, for example, approximately 2 μm (measurement range 20 mm), for example. The radius of curvature is 25 m. Based on the calculation of a 4-inch substrate, the SORI value is approximately 50 μm by an etching process after the slicing step. This value is significantly smaller than SORI value 21 (10 μm (measurement range 20 mm)) immediately after the first slicing step set forth above.

Preferably in the substrate etching step (S20: FIG. 6), one of first main surface 11A and second main surface 11B of first intermediate substrate 11 is etched such that the SORI value in a direction perpendicular to the direction of slicing ingot 1 is reduced. In other words, by etching first intermediate substrate 11 having a first SORI value 21 in a direction perpendicular to the direction of slicing ingot 1, a second intermediate substrate 12 having a second SORI value 22 smaller than the first SORI value 21 in a direction perpendicular to the direction of slicing ingot 1 is formed.

Then, a substrate attaching step (S30: FIG. 6) is executed. At this step, second intermediate substrate 12 formed by the above-described step (S20: FIG. 6) is fixed to a grinding plate. Specifically, referring to FIG. 10, a second intermediate substrate 12 having a second SORI value 22 is fixed to grinding plate 40 via an adhesive 30. At this stage, second intermediate substrate 12 is arranged such that the side of second intermediate substrate 12 having convex warpage (for example, first main surface 12A) is in contact with adhesive 30. Second intermediate substrate 12 may be fixed to grinding plate 40 in a state where only the central region is brought into contact with adhesive 30 and the outer peripheral portion is not in contact with adhesive 30.

For grinding plate 40, a porous ceramic plate, for example, may be employed. In this case, second intermediate substrate 12 is attracted to grinding plate 40 by vacuuming to be fixed thereto. In other words, second intermediate substrate 12 is fixed to grinding plate 40 without adhesive 30.

In the case where second intermediate substrate 12 is fixed to grinding plate 40 by means of adhesive 30, the area of second intermediate substrate 12 with great warpage in contact with adhesive 30 is smaller than that of second intermediate substrate 12 with small warpage. Further, in the case where second intermediate substrate 12 is fixed to grinding plate 40 by vacuuming, second intermediate substrate 12 with greater warpage has a smaller area in contact with grinding plate 40 than second intermediate substrate 12 with small warpage. In either case, the force of holding second intermediate substrate 12 by means of grinding plate 40 is smaller for second intermediate substrate 12 with greater warpage as compared to second intermediate substrate 12 with small warpage. Therefore, second intermediate substrate 12 with greater warpage will drop off more readily from grinding plate 40 than second intermediate substrate 12 with small warpage. In the fabrication method according to the first embodiment, the etching step is executed to reduce warpage, prior to attaching second intermediate substrate 12 to grinding plate 40. Thus, the effect of suppressing second intermediate substrate 12 from dropping off from grinding plate 40 during a subsequent grinding step can be achieved effectively.

Next, a second main surface lapping step (S40: FIG. 6) is executed. Specifically, by grinding the back side (second main surface 12B) of second intermediate substrate 12 using an abrasive, second main surface 12B is partially removed. As shown in FIG. 10, second intermediate substrate 12 fixed to grinding plate 40 is arranged such that second main surface 12B faces a surface plate 50 for lapping. For example, by rotating surface plate 50 relative to second main surface 12B while providing a flow of slurry including abrasive grains between surface plate 50 and second main surface 12B, second main surface 12B of second intermediate substrate 12 is ground. Here, diamond grains, for example, are employed as the abrasive. The grain size of the diamond abrasive is approximately 1-6 μm, for example. For surface plate 50 directed to lapping, iron, copper, tin or the like, for example, can be employed.

Then, a second main surface MP (Mechanical Polishing) step (S50: FIG. 6) is executed. Specifically, by mechanically polishing the back side (second main surface 12B) of second intermediate substrate 12 using an abrasive, second intermediate substrate 12 is partially removed. For the abrasive, diamond grains, for example, are employed. The grain size of the diamond abrasive is greater than or equal to 0.1 μm and less than or equal to 3 μm, for example. For surface plate 50 for MP, a metal surface plate such as of tin or tin alloy, a resin surface plate, an abrasive cloth, or the like, can be employed.

Thus, by polishing second main surface 12B of second intermediate substrate 12 as set forth above, a third intermediate substrate 13 (refer to FIG. 13) having a third SORI value 23 smaller than second SORI value 22 is formed.

Then, a second main surface CMP step (S60: FIG. 6) is executed. Specifically, CMP (Chemical Mechanical Polishing) is applied to second main surface 13B of third intermediate substrate 13 subjected to MP in the aforementioned step (S50: FIG. 6). The abrasive for CMP must be of a material softer than silicon carbide to reduce the surface roughness and/or the damaged layer. For the abrasive in CMP, colloidal silica, fumed silica, alumina, and the like, for example, may be employed. For the abrasive cloth directed to CMP, a non-woven cloth or suede may be employed. Accordingly, a fourth intermediate substrate 14 (refer to FIG. 14) having a first main surface 14A and second main surface 14B opposite to each other, and a fourth SORI value 24 smaller than third SORI value 23, is formed. As shown in FIG. 14, this step (S60: FIG. 6) may have the warpage in the opposite direction (for example, change from concave to convex in shape).

Then, a substrate detachment step (S70: FIG. 6) is executed. Specifically, fourth intermediate substrate 14 subjected to CMP at the aforementioned step (S60: FIG. 6) is detached from grinding plate 40. Then, for the purpose of mechanical polishing or the like on first main surface 14A of fourth intermediate substrate 14, fourth intermediate substrate 14 is fixed to grinding plate 40 such that second main surface 14B is brought into contact with adhesive 30.

Then, a first main surface lapping step (S80: FIG. 6) is executed. Specifically, in a manner similar to that of the second main surface lapping step (S40), first main surface 14A of fourth intermediate substrate 14 is arranged to face surface plate 50, and the surface of fourth intermediate substrate 14 (first main surface 14A) is polished.

Then, a first main surface MP step (S90: FIG. 6) is executed. Specifically, in a manner similar to that of the second main surface MP step (S50: FIG. 6), first main surface 14A of fourth intermediate substrate 14 is mechanically polished.

Then, a first main surface CMP step (S100: FIG. 6) is executed. Specifically, in a manner similar to that the second main surface CMP step (S60: FIG. 6), first main surface 14A of fourth intermediate substrate 14 is subjected to chemical mechanical polishing.

Then, a substrate cleaning step (S110: FIG. 6) is executed. For example, fourth intermediate substrate 14 is immersed in a cleaning solution. By applying ultrasonic waves towards the cleaning solution, fourth intermediate substrate 14 is cleaned. A frequency of the ultrasonic wave can be set greater than or equal to 50 kHz and less than or equal to 2 MHz, for example.

By the step set forth above, silicon carbide substrate 10 having first main surface 10A and second main surface 10B opposite to each other is completed. At silicon carbide substrate 10 fabricated by the fabrication method according to the present embodiment, the surface (first main surface 10A) has a surface roughness Rms of approximately 0.073 nm, for example, whereas the back side (second main surface 10B) has a surface roughness Rms of approximately 4-6 nm, for example. The SORI value of silicon carbide substrate 10 is, for example, approximately 22.1 μm (measurement range 4 inches), and the TTV value is, for example, approximately 2.7 μM (measurement range 4 inches).

The advantageous effect of the first embodiment will be described hereinafter.

By etching at least one of first main surface 11A and second main surface 11B of first intermediate substrate 11 according to the fabrication method of silicon carbide substrate 10 of the first embodiment, a second intermediate substrate 12 having a second SORI value 22 smaller than first SORI value 21 is formed. Then, at least one of first main surface 12A and second main surface 12B of second intermediate substrate 12 is ground. In other words, after the warpage of silicon carbide substrate 10 is reduced by etching, a grinding step on silicon carbide substrate 10 is performed. Therefore, the drop off of silicon carbide substrate 10 from grinding plate 40 during a grinding step due to great warpage of silicon carbide substrate 10 can be suppressed. As a result, second intermediate substrate 12 can be ground favorably, leading to reduction in the warpage of silicon carbide substrate 10.

Further, both first main surface 13A and second main surface 13B of third intermediate substrate 13 are subjected to CMP according to a fabrication method of silicon carbide substrate 10 of the first embodiment. Accordingly, the warpage of silicon carbide substrate 10 can be further reduced.

According to the fabrication method of silicon carbide substrate 10 of the first embodiment, the step of forming second intermediate substrate 12 may include the step of wet-etching at least one of first main surface 11A and second main surface 11B of first intermediate substrate 11 using potassium hydroxide. Accordingly, second intermediate substrate 12 with small warpage can be fabricated efficiently.

Furthermore, according to the fabrication method of silicon carbide substrate 10 of the first embodiment, the step of forming second intermediate substrate 12 may include the step of dry-etching at least one of first main surface 11A and second main surface 11B of first intermediate substrate 11 using chlorine gas or fluorine gas. Accordingly, second intermediate substrate 12 with small warpage can be fabricated efficiently.

According to the fabrication method of silicon carbide substrate 10 of the first embodiment, the step of forming second intermediate substrate 12 is performed by etching both first main surface 11A and second main surface 11B of first intermediate substrate 11. Accordingly, second intermediate substrate 12 with small warpage can be fabricated more efficiently.

According to the fabrication method of silicon carbide substrate 10 of the first embodiment, at the step of forming second intermediate substrate 12, first intermediate substrate 11 is etched such that the SORI value in a direction perpendicular to the slicing direction Z of ingot 1 is reduced. Warpage at first intermediate substrate 11 readily occurs in the direction perpendicular to the direction of slicing ingot 1. By performing etching such that the SORI value is reduced in the direction perpendicular to the direction of slicing ingot 1, second intermediate substrate 12 with small warpage can be fabricated more efficiently.

### Second Embodiment

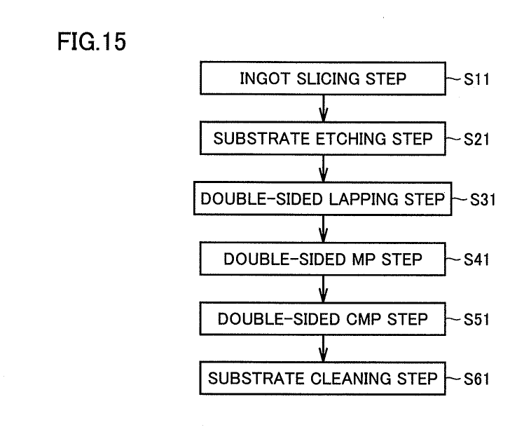

A fabrication method of a silicon carbide substrate according to a second embodiment of the present invention will be described hereinafter with reference to FIG. 15.

First, an ingot slicing step (S11: FIG. 15) is executed. Specifically, in a manner similar to that of the ingot slicing step described in the first embodiment (S10: FIG. 6), ingot 1 formed of silicon carbide is sliced to form first intermediate substrate 11 (refer to FIG. 11) having first main surface 11A and second main surface 11B opposite to each other, and first SORI value 21 (FIG. 11).

Then, a substrate etching step (S21: FIG. 15) is performed. Specifically, in a manner similar to that of the substrate etching step described in the first embodiment (S20: FIG. 6), at least one of first main surface 11A and second main surface 11B of first intermediate substrate 11 is etched to form a second intermediate substrate 12 having second SORI value 22 smaller than first SORI value 21.

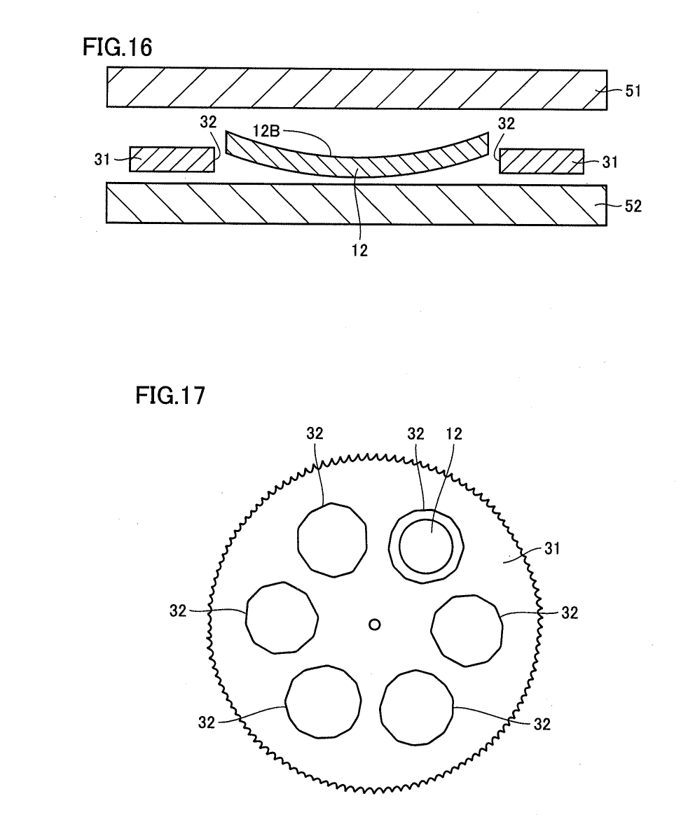

Then, a double-sided lapping step (S31: FIG. 15) is performed. Specifically, referring to FIG. 17, second intermediate substrate 12 is arranged in a hole 32 formed in a carrier 31. The size of hole 32 is larger than the size of second intermediate substrate 12. Referring to FIG. 16, second intermediate substrate 12 located in hole 32 of carrier 31 is arranged between an upper surface plate 51 and a lower surface plate 52. Upper surface plate 51 rotates, for example, in the clockwise direction, whereas lower surface plate 52 rotates, for example, in the counterclockwise direction, so that first main surface 12A and second main surface 12B of second intermediate substrate 12 are ground simultaneously.

Before the double-sided lapping step (S31: FIG. 15) is executed in the present embodiment, the substrate etching step (S21: FIG. 15) is executed. Therefore, the warpage of second intermediate substrate 12 is reduced. Thus, the drop off of second intermediate substrate 12 from hole 32 in carrier 31 can be suppressed.

Then, a double-sided MP step (S41: FIG. 15) is performed. Specifically, first main surface 12A and second main surface 12B of second intermediate substrate 12 are mechanically polished simultaneously. The material of the abrasive and the surface plate employed in this step (S41: FIG. 15) is similar to those described in the second main surface MP step (S50: FIG. 6) set forth in the first embodiment.

By grinding second surface 12B of second intermediate substrate 12, a third intermediate substrate 13 having a third SORI value 23 smaller than second SORI value 22 is formed (refer to FIG. 13).

Then, a double-sided CMP step (S51: FIG. 15) is executed. Specifically, first main surface 13A and second main surface 13B of third intermediate substrate 13 subjected to the double-sided MP step in the aforementioned step (S41: FIG. 15) are subject to chemical mechanical polishing at the same time. The material of the abrasive and the surface plate employed in this step (S51: FIG. 15) is similar to those described in the second main surface CMP step (S60: FIG. 6) set forth in the first embodiment.

Then, a substrate cleaning step (S61: FIG. 15) is executed. This step is similar to the substrate cleaning step (S110: FIG. 6) described in the first embodiment. Thus, silicon carbide substrate 10 having first main surface 10A and second main surface 10B opposite to each other is completed. Surface roughness Rms of the surface (first main surface 10A), surface roughness Rms of the back side (second main surface 10B), and the values of SORI and TTV of silicon carbide substrate 10 fabricated by the fabrication method of the second embodiment are similar to those of silicon carbide substrate 10 fabricated by the fabrication method of the first embodiment.

In the fabrication method of a silicon carbide substrate according to the second embodiment, the step of forming third intermediate substrate 13 is performed by grinding both first main surface 12A and second main surface 12B of second intermediate substrate 12 at the same time. Accordingly, the time required for fabricating silicon carbide substrate 10 can be shortened while reducing the warpage of silicon carbide substrate 10.

Although the present invention has been described and illustrated in detail, it is clearly understood that the same is by way of illustration and example only and is not to be taken by way of limitation, the scope of the present invention being interpreted by the terms of the appended claims.

What is claimed is:

1. A fabrication method of a silicon carbide substrate, comprising the steps of:
forming a first intermediate substrate having a first main surface and a second main surface opposite to each other, and a first SORI value, by slicing a silicon carbide ingot,
forming a second intermediate substrate having a second SORI value smaller than said first SORI value, by etching at least one of said first main surface and said second main surface of said first intermediate substrate, and
forming a third intermediate substrate having a third SORI value smaller than said second SORI value, by grinding at least one of said first main surface and said second main surface of said second intermediate substrate.

2. The fabrication method of a silicon carbide substrate according to claim 1, further comprising the step of applying CMP to both said first main surface and said second main surface of said third intermediate substrate.

3. The fabrication method of a silicon carbide substrate according to claim 1, wherein said step of forming a third intermediate substrate is performed by grinding both said first main surface and said second main surface of said second intermediate substrate simultaneously.

4. The fabrication method of a silicon carbide substrate according to claim 1, wherein said step of forming a second intermediate substrate includes the step of wet-etching at least one of said first main surface and said second main surface of said first intermediate substrate using potassium hydroxide.

5. The fabrication method of a silicon carbide substrate according to claim 1, wherein said step of forming a second intermediate substrate includes the step of dry-etching at least one of said first main surface and said second main surface of said first intermediate substrate using chlorine gas or fluorine gas.

6. The fabrication method of a silicon carbide substrate according to claim 1, wherein said step of forming a second intermediate substrate is performed by etching both said first main surface and said second main surface of said first intermediate substrate.

7. The fabrication method of a silicon carbide substrate according to claim 1, wherein said first intermediate substrate is etched such that a SORI value is reduced in a direction perpendicular to a direction of slicing said ingot at said step of forming a second intermediate substrate.

8. A silicon carbide substrate of at least 4 inches in diameter, comprising:
a first main surface and a second main surface opposite to each other,
said first main surface having a surface roughness Rms less than or equal to 0.2 nm,
said second main surface having a surface roughness Rms less than 10 nm, and
a SORI value less than or equal to 23 and a TTV value less than or equal to 3 μm.
